(19) United States
(12) Patent Application Publication
(10) Pub. No.: US 2023/0215478 A1
(43) Pub. Date: Jul. 6, 2023

(54) MULTI-PHASE CLOCKING SCHEME FOR A MEMORY DEVICE

(71) Applicant: Intel Corporation, Santa Clara, CA (US)

(72) Inventors: Sriram Balasubrahmanyam, Folsom, CA (US); Arti Sharma, Santa Clara, CA (US); Jong Tai Park, Pleasanton, CA (US); Tri Tran, Elk Grove, CA (US)

(21) Appl. No.: 18/148,230

(22) Filed: Dec. 29, 2022

(51) Int. Cl. G11C 7/22; G11C 7/10

(52) U.S. Cl. CPC G11C 7/222; G11C 7/1066

(57) ABSTRACT

Technology to provide a multi-phase clocking scheme for a memory device includes generating, based on a first clock signal having a first frequency, multi-phase clock signals for a memory device having a second frequency, where the second frequency is a fraction of the first frequency, generating local clock signals for data channels of the memory device based on the multi-phase clock signals, where the local clock signals are synchronous with respective rising edges of the multi-phase clock signals, and providing output data for the data channels of the memory device in an output data sequence based on the local clock signals. In some embodiments, the second frequency is one-half of the first frequency, and the multi-phase clock signals are four-phase clock signals. In some embodiments, the output data is clocked out at an effective rate equal to the first frequency based on the local clock signals.

### TECHNICAL FIELD

Embodiments generally relate to memory devices. More particularly, embodiments relate to a multi phase clocking scheme for a memory device.

### BACKGROUND

Current memory devices, such as three-dimensional (3D) NAND memory devices, use a memory clocking scheme that relies on both rising edge and falling edge of a high speed X1 clock for generating local first-in first out (FIFO) and serializer clocks. As the X1 clock speed increases, however, the pulse width of the X1 clock in the memory clocking system becomes increasingly narrow, and duty-cycle degradation becomes a significant problem due to systematic and random local variations in logic circuitry as well as aging. At higher dock speeds, this degradation becomes exponentially difficult to recover and impacts memory input/output (IO) timing and memory performance.

### BRIEF DESCRIPTION OF THE DRAWINGS

The various advantages of the embodiments will become apparent to one skilled in the art by reading the following specification and appended claims, and by referencing the following drawings, in which:

FIGS. 1A-1C provide diagrams illustrating a memory clocking system in used in existing designs;

FIGS. 2A-2C provide diagrams illustrating an example memory clocking system according to one or more embodiments;

FIG. 3A-3C provide diagrams illustrating example signals in a memory clocking system according to one or more embodiments;

FIG. 4 provides a block diagram illustrating an example memory device according to one or more embodiments;

FIG. 5 provides a block diagram illustrating an example of a data storage device according to one or more embodiments;

FIG. 6 provides a flow diagram illustrating an example method of operating a memory clocking system according to one or more embodiments;

FIG. 7 is a block diagram of an example of a performance-enhanced computing system according to one or more embodiments; and

FIG. 8 is a block diagram illustrating an example semiconductor apparatus according to one or more embodiments.

### DESCRIPTION OF EMBODIMENTS

A performance-enhanced memory device as described herein provides a multi-phase clocking scheme based on a divided clock with several different phases, where the memory clocking system uses only the rising edges of the clock signals for synchronization. As one example, a memory clocking system as described herein uses a divide-by-two clock with four phases (0, 90, 180 and 270 degrees), where the four-phase clock rising edges are used to generate the divided clocks for FIFO and serializer components by synchronizing at rising edge of every divide-by-2 phase clock. The four-phase clock signals are generated with a rate of one-half the frequency of the incoming clock signals, but in combination the four-phases provide for clocking the output data DQ0, . . . , DQ7 at the equivalent of the higher incoming clock rate.

By using only the rising edge for synchronization, the clock signals in the memory clocking system are duty-cycle independent, thus avoiding or minimizing the clock signal degradation in existing designs at higher clock speeds. Additionally, the technology avoids transferring clock signals at the highest clock speed (X1) through clock trees and downstream across the clocking paths for the data DQ channels and, instead, transfers X2 (one-half the rate of X1) clock signals through the clocking system, which reduces effects due to higher clock rates. Moreover, the use of multi-phase clock signals enable the clocking system to maintain the highest effective rate for clocking the output data. The technology disclosed herein helps improve the overall performance of memory devices by enabling operation at higher clock speeds (such as, e.g., clock speeds exceeding 1.6GT/s and/or clock speeds exceeding twice the current operating speeds) using the same basic CMOS memory technology. The disclosed technology further helps reduce manufacturing cost from one speed node to the next (e.g., devices operable at increasing high clock speeds), and improves end-of life aging by making system design independent of duty-cycle distortion.

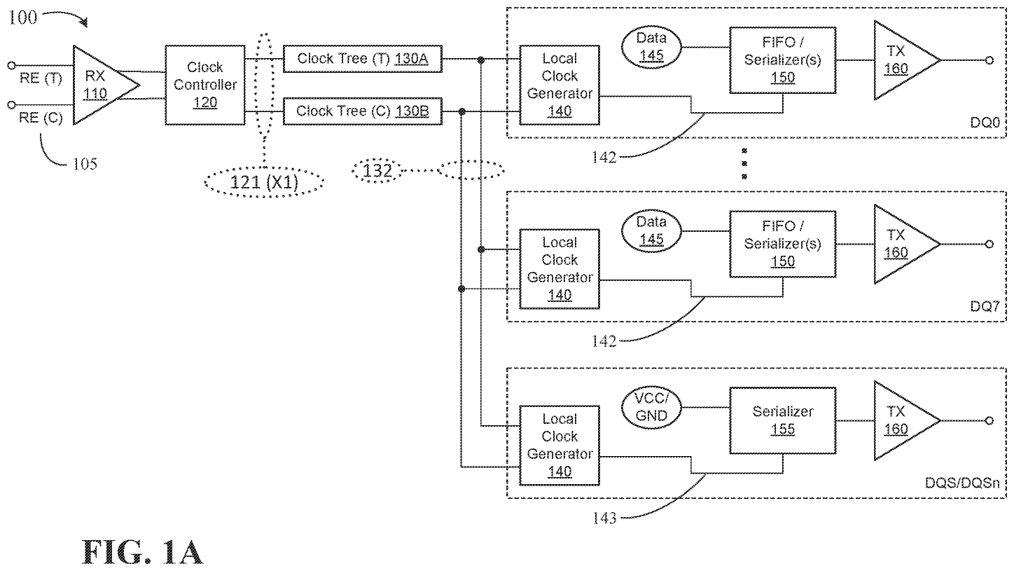

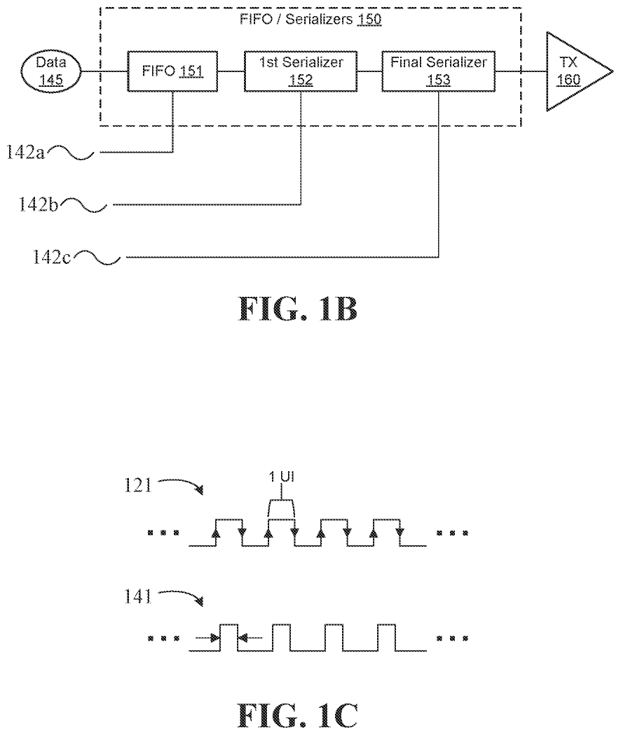

FIG. 1A provides a block diagram illustrating a memory clocking system 100 (for memory reads) as used in existing designs. As shown in FIG. 1A, the memory clocking system 100 includes a receiver 110, a clock controller 120, clock trees 130, local clock generators 140, and a data pipeline (including data 145, FIFO/Serializer(s) 150, and a transmitter 160) for data outputs DQ0 through DQ7; as illustrated in FIG. 1A, the components for each data channel DQ0, . . . , DQ7 are typically the same or similar. DQ0 through DQ7 represent data out signals (e.g., data out bus) for the memory device. The transmitter 160 is an output driver to drive the respective data output signal. The memory clocking system 100 also includes a local clock generator 140, a serializer 155 and a transmitter 160 for output signal DQS, which represents an output data clocking signal indicating when output data can be latched by a device receiving (e.g., reading) the output data DQ0-DQ7. In some cases there is also a DQSn signal (representing a complement to the DQS signal).

The receiver 110 receives an incoming differential read clock signal 105 (designated as RE(T) and RE(C), where “T” designates True and “C” designates Complement) and provides a differential clock signal to the clock controller 120. The incoming clock signal 105 is generated by a memory controller—e.g., a solid state drive (SSD) controller, not shown in FIG. 1A, that is part of a SSD platform—external to the individual memory device/chip. In some cases the incoming clock signal 105 and the output of the receiver 110 are single ended rather than differential signals. The clock controller 120 generates T and C clock signals 121 (labeled X1 to indicate they are provided at the input clock rate) that are fed into a true clock tree 130A and a complementary clock tree 130B, respectively. Because the outputs 132 of the clock trees 130 are 180 degrees out of phase, they can be said to represent bi-phase (but not multi-phase) clock signals. The outputs 132 of the clock trees 130 are fed into local clock generators 140, a series of which generate local clock signals 142 to control each part of the data pipeline(s) (for DQ0 through DQ7) that are synchronized to both rising edge and falling edge of the clock tree outputs 132. A local clock generator 140 for DQS generates local clock signals 143 for the serializer 155. Of note, the respective outputs DQ0 through DQ7 and DQS are all clocked out at the same phase (not bi-phase or multi-phase). The clock generators 140 can include dividers to generate divided signals, and also logic to match propagation delays in the data pipeline (or other delays in the data path beyond the data pipeline).

FIG. 1B provides a block diagram illustrating a data pipeline for one of the data channels (e.g., DQ0, . . . , or DQ7) in the memory clocking system 100 as used in existing designs. Typically, the data pipeline is the same or similar for each of the data channels. The data pipeline includes the data 145, a FIFO 151, a first serializer 152, a final serializer 153 and the transmitter 160. The FIFO 151, the first serializer 152, and the final serializer 153 are components of the FIFO/serializers 150 (FIG. 1A). In some cases, fewer or additional serializers can be included. Local clock signals 142 (FIG. 1A) include FIFO clock signals 142a to control the FIFO 151, high divided clock signals 142b to control the first serializer 152, and low divided clock signals 142c to control the final serializer 153. The low divided clock signals 142c are in particular synchronized based on the rising edge and falling edge of the X1 clock signal. Some of the local clock signals 142 can include signals divided down (e.g., by the local clock generator 140) to provide X2 clocks (one-half of the X1 rate) and/or X4 clocks (one-quarter of the X1 rate), etc. That is, an X1 clock is twice the rate of an X2 clock, and an X1 clock is four times the rate of an X4 clock. For example, in some cases the FIFO clock signals 142a include signals at the X4 rate. As another example, in some cases the high divided clock signals 142b include signals at the X4 and/or the X2 rate. As another example, in some cases the low divided clock signals 142c include signals at the X1 rate.

For DQS, the local clock signals 143 include low divided clock signals (similar to the low divided clock signals 142c). The serializer 155 includes typically a single (e.g., final) serializer, thus FIFO clock signals and high divided clock signals are typically unused for DQS.

FIG. 1C provides a diagram illustrating some of the signals in the memory clocking system 100. A clock signal 121 (an output of the clock controller 120) is shown at the X1 rate, where the rising edge and falling edge are used to generate and/or synchronize downstream clock signals (including, for example, a downstream clock signal 141). The clock signal 121 has a pulse width of 1 unit interval (UI), where a unit interval reflects the rate of change of data. The downstream clock signal 141 is representative of any of the clock signals downstream of the clock trees 130, for example as an input to one of the local clock generators 140 and/or as an output of a local clock generator 140. As illustrated in FIG. 1C, the downstream clock signal 141 has a substantially narrowed pulse width, indicated by the arrows, that is caused by the degradation due to reliance on the rising edges and falling edges of the preceding clock signals (e.g., the clock signal 121). The amount of degradation/narrowing can be based on the X1 clock rate and how far downstream the clock signal 141 is located. For example, as the X1 rate increases, the pulse width of the clock signal 141 decreases.

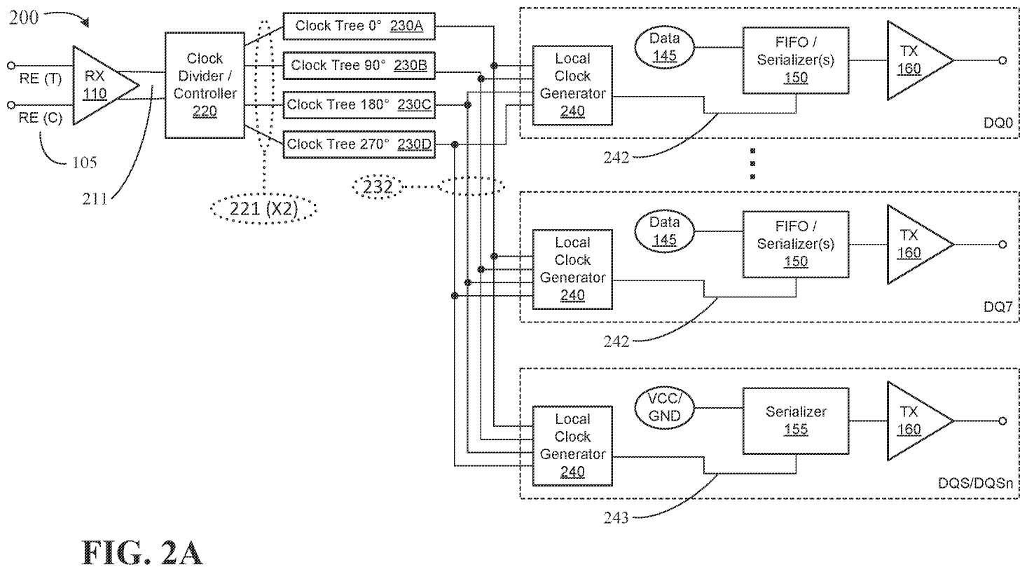

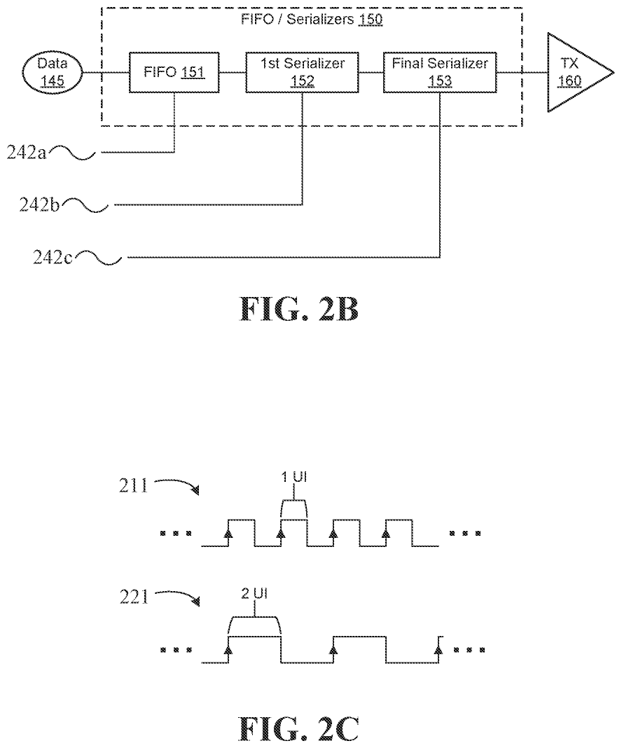

FIG. 2A provides a block diagram illustrating an example of an improved memory clocking system 200 (for memory reads) according to one or more embodiments, with reference to components and features described herein including but not limited to the figures and associated description. The memory clocking system 200 includes components and features that are the same as or similar to those in the memory clocking system 100 (FIGS. 1A-1B, already discussed), and those components and features will not be repeated except as necessary to describe the new/additional components and features shown. As shown in FIG. 2A, the memory clocking system 200 includes a clock divider/controller 220, clock trees 230, and local clock generators 240. The clock divider/controller 220 receives a clock signal 211 (as output from the receiver 110) which is at the X1 rate (e.g., the same rate as the incoming clock signal 105). The clock divider/controller 220 divides the clock signal 211 into multi-phase clock signals 221 having a rate of X2 (e.g., a rate of one-half the X1 rate). Thus, the multi-phase clock signals have a rate X2 that is a fraction (½) of the incoming clock rate X1. Put another way, the incoming clock rate X1 is a multiple (two times) of the divided rate X2 for the multi-phase clock signals. In some embodiments, other divided rates (e.g., X4, or ¼) can be used for generating the multi-phase clock signals. The clock divider/controller 220 can use, e.g., one or more dividers to generate divided clock signals.

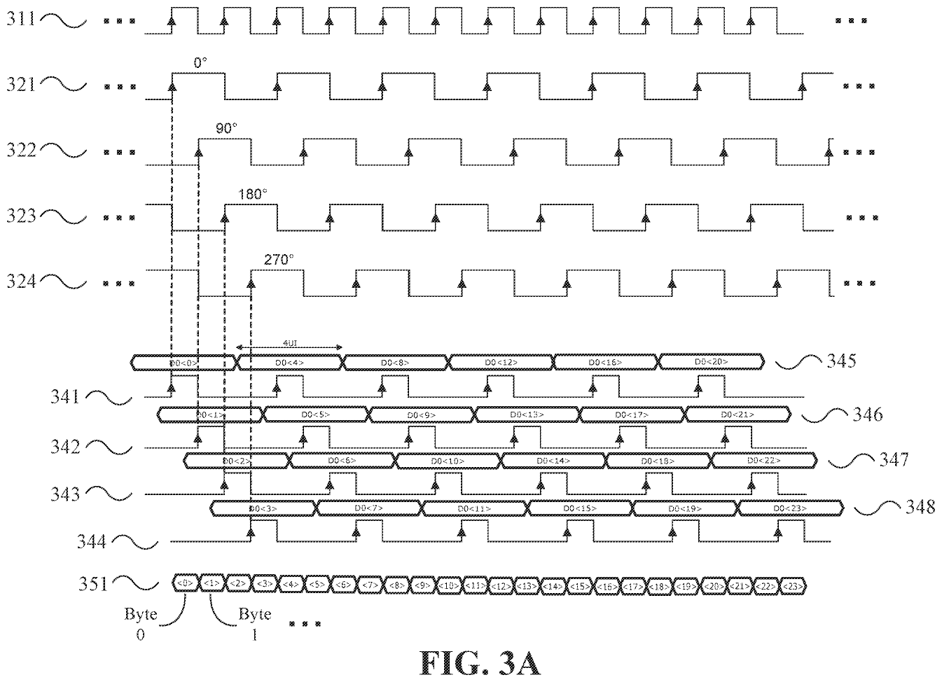

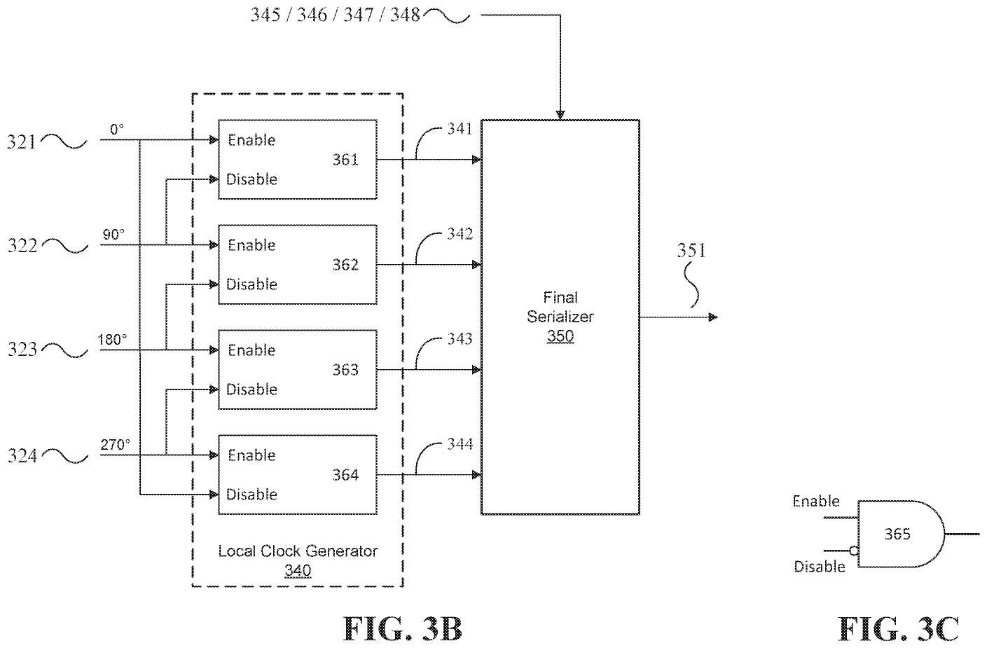

In some embodiments, the multi-phase clock signals 221 are generated with a phase of 0 degrees, 90 degrees, 180 degrees, and 270 degrees, respectively, for the example 4-phase signals illustrated in FIGS. 2A and 3A-3B herein. In some embodiments, multi-phase clock signals can be generated with other phase groupings (e.g., 3-phase, 5-phase, 6-phase, 8-phase, etc.). As illustrated in FIG. 2A, the 4-phase clock signals 221 are fed into 4 clock trees 230—the clock tree 230A (0 degrees), the clock tree 230B (90 degrees), the clock tree 230C (180 degrees), and the clock tree 230D (270 degrees).

The multi-phase clock signals 232 as output from the clock trees 230 are provided at the X2 rate, and are fed into local clock generators 240. A series of local clock generators 240 generate local clock signals 242 to control each part of the data pipeline(s) (for DQ0 through DQ7) that are synchronized to the rising edge (only) of the multi-phase clock signals 232. A local clock generator 240 for DQS generates local clock signals 243 for the serializer 155, also synchronized to the rising edge (only) of the multi-phase clock signals 232. As the local clock generators 240 generate, based on logic, signals synchronized to the rising edge (only) of the multi-phase clock signals 232, the logic in the local clock generators thus bypass use of trailing or falling edges of the multi-phase clock signals 232 to generate or synchronize the local clock signals 242 or 243. Of note, the respective outputs DQ0 through DQ7 and DQS are clocked out based on multi-phase clock signals, as described further herein with reference to FIGS. 3A-3B. The clock generators 240 can include dividers to generate divided signals, and also logic to match propagation delays in the data pipeline (or other delays in the data path beyond the data pipeline).

FIG. 2B provides a block diagram illustrating an example data pipeline for one of the data channels (e.g., DQ0, . . . , or DQ7) in the memory clocking system 200 according to one or more embodiments, with reference to components and features described herein including but not limited to the figures and associated description. The data pipeline illustrated in FIG. 2B includes components and features that are the same as or similar to those in the data pipeline illustrated in FIG. 1B (already discussed), and those components and features will not be repeated except as necessary to describe the new/additional components and features shown. As shown in FIG. 2B, local clock signals 242 (FIG. 2A) include FIFO clock signals 242a to control the FIFO 151, high divided clock signals 242b to control the first serializer 152, and low divided clock signals 242c to control the final serializer 153. Some of the local clock signals 242 can include signals divided down (e.g., by the local clock generator 240) to provide X4 clocks (one-quarter of the X1 rate), etc. For example, in some cases the FIFO clock signals 242a include signals at the X4 rate. As another example, in some cases the high divided clock signals 242b include signals at the X4 and/or the X2 rate. As another example, in some cases the low divided clock signals 242c provide signals, based on the multi-phasing, equivalent to signals at the X1 rate.

Depending upon the precise construction and timing involved in the FIFO 151, the FIFO clock signals 242a can include signals of single phase, multi-phase, or a combination thereof. Similarly, depending upon the precise construction and timing involved in the first serializer 152, the high divided clock signals 242b can include signals of single phase, multi-phase, or a combination thereof. The low divided clock signals 242c are multi-phase signals, as illustrated in the examples of FIGS. 3A-3B. Of note, each of the data channels DQ0, DQ1, . . . , DQ7 have the same phasing so that the data channels are clocked out in phase with each other.

FIG. 2C provides a diagram illustrating examples of some of the signals in the memory clocking system 200. The clock signal 211 (input to the clock divider/controller 220) is shown at the X1 rate, where the rising edge (only) is used to generate and/or synchronize the output clock signals 221. The clock signal 121 has a pulse width of 1 unit interval (UI). Further shown in FIG. 2C is one of the clock signals 221 (as output by the clock divider/controller 220). The example clock signal 221 shown in FIG. 2C is illustrated with a 0 degree phase, and has a rate of X2. The example clock signal 221 has a pulse width of 2 UI (i.e., twice the pulse width of the clock signal 211).

Some or all components or features of in the memory clocking system 200 (including, e.g., the clock divider/controller 220, the clock trees 230, and/or the local clock generators 240) can be implemented using a field programmable gate array (FPGA), an application specific integrated circuit (ASIC), other hardware logic (e.g., logic circuitry), via a controller with software or firmware, and/or in a combination of a controller with software/firmware and logic, an FPGA or ASIC. More particularly, components of the memory clocking system 200 can be implemented in one or more modules as a set of program or logic instructions stored in a machine- or computer-readable storage medium such as random access memory (RAM), read only memory (ROM), programmable ROM (PROM), firmware, flash memory, etc., in hardware, or any combination thereof. For example, hardware implementations can include configurable logic, fixed-functionality logic, or any combination thereof. Examples of configurable logic include suitably configured programmable logic arrays (PLAs), FPGAs, complex programmable logic devices (CPLDs), and general purpose microprocessors. Examples of fixed-functionality logic include suitably configured ASICs, combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

FIG. 3A provides a diagram illustrating example signals in a memory clocking system (such as, e.g., the memory clocking system 200) according to one or more embodiments, with reference to components and features described herein including but not limited to the figures and associated description. The clock signal 311 is an example of a clock signal, at X1 rate, that is provided as input to the clock divider/controller 220. In embodiments, the clock signal 311 corresponds to the clock signal 211 (FIGS. 2A and 2C, already discussed). Multi-phase clock signals 321, 322, 323 and 324 are examples of multi-phase clock signals provided at the X2 rate as output by the clock divider/controller 220, and have a pulse width of (approximately) 2 UI. In embodiments, the multi-phase clock signals 321-324 correspond to the multi-phase clock signals 221 (FIG. 2A, already discussed). In the examples of FIG. 3A, the multi-phase clock signals 321-324 are 4-phase clock signals, where the clock signal 321 has a phase of 0 degrees (e.g., relative to the clock signal 311), the clock signal 322 has a phase of 90 degrees (e.g., relative to the clock signal 311 and/or to the clock signal 321), the clock signal 323 has a phase of 180 degrees (e.g., relative to the clock signal 311 and/or to the clock signal 321), and the clock signal 324 has a phase of 270 degrees (e.g., relative to the clock signal 311 and/or to the clock signal 321).

The illustrated example multi-phase clock signals 321-324 are also representative of multi-phase clock signals downstream of the clock trees 230. For example, the multi-phase clock signals 321-324 are representative of the clock signals 232 that are fed into the local clock generators 240 (FIG. 2A, already discussed). In some examples, the multi-phase clock signals 321-324 are representative of some of the X2 rate signals generated by the local clock generators 240.

Also illustrated in FIG. 3A are example local clock signals 341, 342, 343 and 344, which are examples of the low divided clock signals 242c generated by a local clock generator 240 242c to control the final serializer 153 (FIGS. 2A-2B, already discussed). The local clock signals 341, 342, 343 and 344 are provided at the X2 rate (and are also multi-phase), but have a pulse width of (approximately) 1 UI. For example, the clock signal 341 has a phase of 0 degrees and is synchronized to the rising edges of the clock signal 321, the clock signal 342 has a phase of 90 degrees and is synchronized to the rising edges of the clock signal 322, the clock signal 343 has a phase of 180 degrees and is synchronized to the rising edges of the clock signal 323, and the clock signal 344 has a phase of 270 degrees and is synchronized to the rising edges of the clock signal 324.

As shown in FIG. 3A, data elements provided in respective data window sequences 345, 346, 347 and 348 represent examples of the sequencing of data elements for a data channel (DQ0 as illustrated in FIG. 3A) which are incoming to the final serializer 153. Each of the individual data windows in the elements 345-348 has a width of 4 UI. While FIG. 3A illustrates the sequencing of data elements for the data channel DQ0, the other data channels DQ1 through DQ7 have the same or similar timing. As illustrated, these data windows are phased to one of the multi-phase clock signals (e.g., 0 degrees, 90 degrees, 180 degrees, or 270 degrees). For example, the sequence of data windows 345 includes data windows for byte 0, byte 4, byte 8, byte 12, byte 16, byte 20, etc. (it will be understood that data channel DQ0 provides 1 bit in a byte, but the other data channels DQ1 through DQ7 are synchronized with the same phasing as DQ0, such that the windows represent timing for data bytes). Similarly, the sequence of data windows 346 includes data windows for byte 1, byte 5, byte 9, byte 13, byte 17, byte 21, etc., the sequence of data windows 347 includes data windows for byte 2, byte 6, byte 10, byte 14, byte 18, byte 22, etc., and the sequence of data windows 348 includes data windows for byte 3, byte 7, byte 11, byte 15, byte 19, byte 23, etc. Thus, the data window sequences 345-348 collectively present a staggered, multi-phase data sequence, as illustrated in FIG. 3A.

Based on the respective local clock signals 341-344, the respective data channel (e.g., DQ0 as illustrated in FIG. 3A) outputs data elements (e.g., as output by the transmitter 160 following the final serializer 153) according to the active output data windows 351 in the proper sequence—byte 0, byte 1, byte 2, byte 3, byte 4, . . . , byte 23, . . . etc. Thus, the final serializer converts the staggered, multi-phase data sequence (e.g., as input to the final serializer 153) to the sequential data bytes accessed from the NAND memory (output data sequence). The timing of the output data elements per the active output data windows 351 represents a new byte for each UI (e.g., a unit interval, which reflects the rate of change of data), and these data windows 351 are synchronized to the rising edges of the clock signals 341 through 344. The effective output data rate is X1, which is enabled by the multi-phase clocking scheme. The active output data windows for the other data channels (e.g., DQ1 through DQ7) have the same timing as for DQ0 as illustrated in FIG. 3A.

FIG. 3B provides a diagram illustrating a portion of an example of a local clock generator 340 for use in a memory clocking system (such as, e.g., the memory clocking system 200) according to one or more embodiments, with reference to components and features described herein including but not limited to the figures and associated description. In embodiments, the local clock generator 340 corresponds to the local clock generator 240 (FIG. 2A, already discussed). The portion of the local clock generator 340 illustrated in FIG. 3B illustrates generation of the clock signals and timing for the data windows illustrated in FIG. 3A. The clock signals 321-324 (e.g., as shown in FIG. 3A, already discussed) are each provided as inputs to the local clock generator 340 as illustrated, and the local clock generator 340 produces as output the local clock signals 341, 342, 343 and 344 (e.g., as shown in FIG. 3A).

For example, as shown in FIG. 3B the clock signal 321 (0 degrees phase) is provided to an enable input of a first logic element 361 and also to a disable input of a fourth logic element 364. Similarly, the clock signal 322 (90 degrees phase) is provided to an enable input of a second logic element 362 and also to a disable input of the first logic element 361, the clock signal 323 (180 degrees phase) is provided to an enable input of a third logic element 363 and also to a disable input of the second logic element 362, and the clock signal 324 (270 degrees phase) is provided to an enable input of a second logic element 362 and also to a disable input of the first logic element 361.

The portion of the local clock generator 340 shown in FIG. 3B includes example logic elements 361, 362, 363 and 364. The logic elements 361, 362, 363 and 364 are operable to provide a logic “1” (high) output if the enable input is high and the disable input is low; otherwise, if the enable input is low or the disable input is high, the output is a logic “0” (low). A logic gate 365 that is a logic equivalent to the logic element 361 (and, similarly, a logic equivalent to each logic element 362, 363 and 364) is illustrated in FIG. 3C. Accordingly, when the clock signals 321 through 324 (as illustrated in FIG. 3A) are input to the local clock generator 340, the local clock signals 341 though 344 (as illustrated in FIG. 3A) are output by the local clock generator 340 via the logic elements 361 through 364. The local clock signals 341 through 344 are provided to a final serializer 350 (which, in embodiments, is equivalent to the final serializer 153 in FIG. 2B, already discussed), which also receives input data elements per the data windows 345 through 348 (as illustrated in FIG. 3A), and provides output data elements for one of the data channels (e.g., DQ0) with active data windows 351 (as illustrated in FIG. 3A).

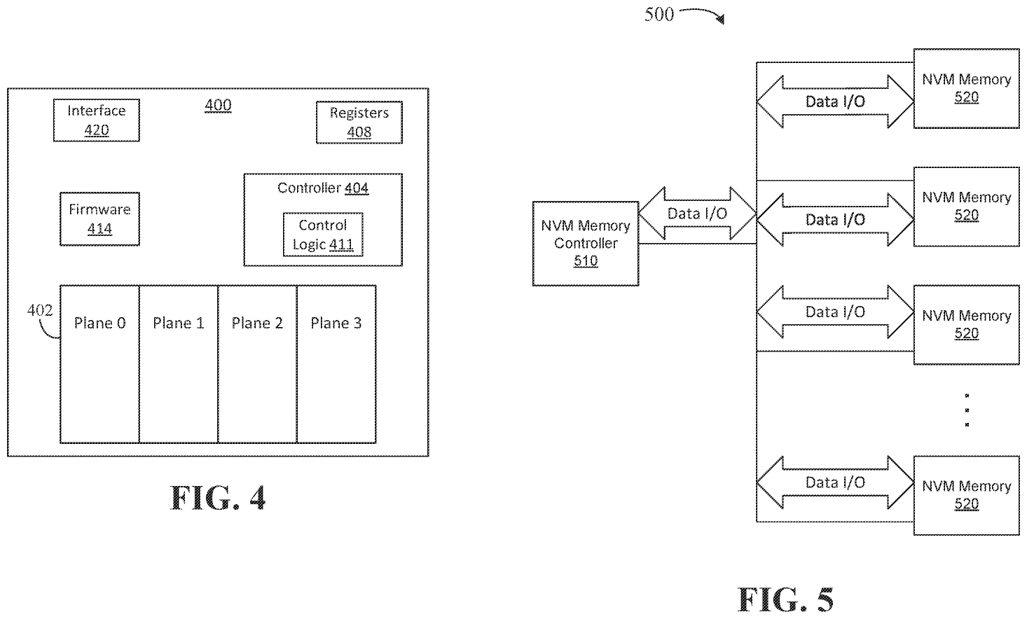

FIG. 4 provides a block diagram for an example memory device 400 according to one or more embodiments, with reference to components and features described herein including but not limited to the figures and associated description. The memory device 400 includes a memory medium 402 for storing data. The memory medium 402 can be a memory or storage medium that can store one or more bits in memory cells. For example, the memory medium 402 can include non-volatile and/or volatile types of memory. In one example, the memory medium 402 includes one or more non-volatile memory dies, each divided into multiple planes or groups. In some examples, the memory medium 402 can include block addressable memory devices, such as NAND technologies. In one example, the memory medium 402 includes a NAND flash memory array such as, e.g., three-dimensional (3D) NAND memory.

The memory medium 402 can also include non-volatile types of memory, such as 3D crosspoint memory (3DxP), or other byte addressable non-volatile memory. Other technologies, such as some NOR flash memory, may be byte addressable for reads and/or writes, and block addressable for erases. The memory medium 402 can include a single-level cell (SLC) NAND storage device, a multi-level cell (MLC) NAND storage device, triple-level cell (TLC) NAND storage device, quad-level cell (QLC) storage device, penta-level cell (PLC) storage device, or a device with higher-levels cells.

The memory device 400 can communicate with a computing platform (e.g., a processor, host system, drive, or external memory controller, etc., not shown in FIG. 4) via an interface 420. For example, in some embodiments the memory device 400 communicates via the interface 420 with a memory controller integrated within the computing platform (e.g., a memory controller integrated within a processor). In one example, the interface 420 is compliant with a standard such as PCI Express (PCIe), serial advanced technology attachment (ATA), a parallel ATA, universal serial bus (USB), and/or other interface protocol.

The memory device 400 includes a controller 404. The controller 404 can communicate with elements of the computing platform (e.g., via the interface 420) to read data from memory medium 402 or write data to memory medium 402. For example, in embodiments the controller 404 is configured to receive requests from the computing platform and generate and perform commands concerning the use of memory medium 402 (e.g., to read data, write, or erase data). Other commands may include, for example, commands to read status, commands to change configuration settings, a reset command, etc. The controller 404 includes control logic 411 for carrying out some or all of the functions of the controller 404. In embodiments the memory device 400 includes firmware 414 coupled to and executed by the controller 404. Although the firmware 414 is illustrated as being separate from the controller 404, in embodiments the firmware 414 is stored in or otherwise integrated within the controller 404 and/or the control logic 411.

In embodiments, the controller 404 and/or the control logic 411 provide some or all of the components and features of the clocking system 200 (FIGS. 2A-2C, already discussed). In some embodiments, some or all of the components and features of the clocking system 200 are provided in other logic on the memory device 400 (not shown separately in FIG. 4).

Some or all components or features of the memory device 400 (including, e.g., the controller 404 and/or the control logic 411) can be implemented using a field programmable gate array (FPGA), an application specific integrated circuit (ASIC), other hardware logic (e.g., logic circuitry), via a controller with software or firmware, and/or in a combination of a controller with software/firmware and logic, an FPGA or ASIC. For example, in embodiments the memory device 400 can be implemented on a single chip or die. More particularly, components of the memory device 400 can be implemented in one or more modules as a set of program or logic instructions stored in a machine- or computer-readable storage medium such as random access memory (RAM), read only memory (ROM), programmable ROM (PROM), firmware, flash memory, etc., in hardware, or any combination thereof. For example, hardware implementations can include configurable logic, fixed-functionality logic, or any combination thereof. Examples of configurable logic include suitably configured programmable logic arrays (PLAs), FPGAs, complex programmable logic devices (CPLDs), and general purpose microprocessors. Examples of fixed-functionality logic include suitably configured ASICs, combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

The controller 404 is coupled with the memory medium 402 to control or command the memory device 400 to cause operations to occur (e.g., read, program, erase, suspend, resume, and other operations). Communication between the memory medium 402 and the controller 404 can include writing to and/or reading from specific registers (e.g., registers 408). Such registers may reside in the controller 404, in the memory medium 402, or external to the controller 404 and the memory medium 402.

In embodiments the controller 404 is coupled to word lines of memory medium 402 to select one of the word lines, apply read voltages, apply program voltages combined with bit line potential levels, or apply erase voltages. In embodiments the controller 404 is also coupled to bit lines of memory medium 402 to read data stored in the memory cells, determine a state of the memory cells during a program operation, and control potential levels of the bit lines to promote or inhibit programming and erasing. Other circuitry can be used for applying selected read voltages and other signals to memory medium 402.

In embodiments the memory medium 402 includes 3D NAND memory, where the memory device 400 has multiple planes per die—such as, e.g., Plane 0, Plane 1, Plane 2, Plane 3, etc. as illustrated in FIG. 4. A plane includes multiple memory cells which may be grouped into blocks. A block is typically the smallest erasable entity in a NAND flash die. In one example, a block includes a number of cells that are coupled to the same bit line. A block includes one or multiple pages of cells. The size of the page can vary depending on implementation. In one example, a page has a size of 16 kB. Page sizes of less or more than 16 kB are also possible (e.g., 512 B, 2 kB, 4 kB, etc.). Each plane also includes a local word line circuit and local word lines coupled to the memory cells in the plane. The data channels DQ0-DQ7 are common to each plane.

In multi-plane configurations, the memory device 400 can receive multiple commands, each to access one of the planes. Independent multi-plane operations enable independent and concurrent operations per plane. Separate state machines for each plane enable application of different bias voltages for each plane to independently and concurrently service requests.

FIG. 5 provides a block diagram for an example data storage device 500 according to one or more embodiments, with reference to components and features described herein including but not limited to the figures and associated description. In embodiments, the data storage device 500 includes or corresponds to a solid state drive platform, and comprises non-volatile memory for data storage. The data storage device 500 includes a memory controller 510 and one or more non-volatile memory devices 520 that are in communication with the memory controller 510. In embodiments, each non-volatile memory device 520 corresponds to the memory device 400 (FIG. 4, already discussed), and can be implemented in a single die/package. In some embodiments, each non-volatile memory device 520 corresponds to a plurality of memory devices 400, and can be implemented in a single die/package or in multiple dies/packages.

The memory controller 510 provides commands and clock signals to the non-volatile memory devices 520. For example, the memory controller 510 provides read clock signals (such as, e.g., read clock signals 105 (FIGS. 1A and 2A, already discussed) to the non-volatile memory devices 520. The memory controller 510 also interfaces with one or more output data buses (data I/O—e.g., DQ0-DQ7) for each of the non-volatile memory devices 520 to read or write data to the individual memory storage devices. For example, the memory controller 510 reads data from a non-volatile memory device 520 via the corresponding data I/O bus (data I/O). In some embodiments, the memory controller 510 has one data I/O bus (one channel) that connects to each data I/O bus of the non-volatile memory devices 520. In some embodiments, the memory controller 510 has multiple data I/O buses (multiple channels), where a respective one of the data I/O buses (for a channel) connects to a data I/O bus of a respective non-volatile memory device 520.

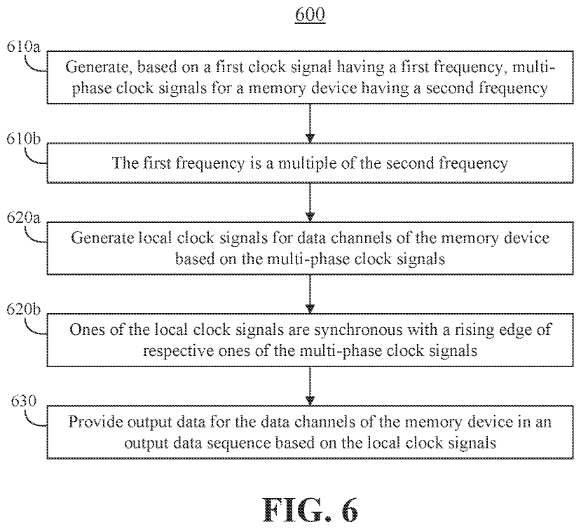

FIG. 6 provides a flow chart illustrating an example method 600 of operating a memory clocking system according to one or more embodiments, with reference to components and features described herein including but not limited to the figures and associated description. The method 600 can generally be implemented in the memory clocking system 200 (FIGS. 2A-2C, already discussed) and/or via components of the memory device 400 (such as, e.g., via the control logic 411 or the firmware 414 in FIG. 4, already discussed). More particularly, the method 600 can be implemented using a field programmable gate array (FPGA), an application specific integrated circuit (ASIC), other hardware logic (e.g., logic circuitry), via a controller with software or firmware, and/or in a combination of a controller with software/firmware and logic, an FPGA or ASIC. Further, aspects of the method 600 can be implemented in one or more modules as a set of program or logic instructions stored in a machine- or computer-readable storage medium such as random access memory (RAM), read only memory (ROM), programmable ROM (PROM), firmware, flash memory, etc., in hardware, or any combination thereof. For example, hardware implementations can include configurable logic, fixed-functionality logic, or any combination thereof. Examples of configurable logic include suitably configured programmable logic arrays (PLAs), FPGAs, complex programmable logic devices (CPLDs), and general purpose microprocessors. Examples of fixed-functionality logic include suitably configured ASICs, combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Illustrated block 610a provides for generating, based on a first clock signal having a first frequency, multi-phase clock signals for a memory device having a second frequency, where at block 610b the second frequency is a fraction of the second frequency. In some embodiments, the multi-phase clock signals are generated based on dividing the first clock signal. In some embodiments, the second frequency is one-half of the first frequency. In some embodiments, the multi-phase clock signals are four-phase clock signals. In some embodiments, the four-phase clock signals include clock signals at a phase of 0 degrees, 90 degrees, 180 degrees, and 270 degrees, respectively. Illustrated block 620a provides for generating local clock signals for data channels of the memory device based on the multi-phase clock signals, where at block 620b the local clock signals are synchronous with respective rising edges of the multi-phase clock signals. At block 630, output data is provided for the data channels of the memory device in an output data sequence based on the local clock signals. In some embodiments, the output data is clocked out at an effective rate equal to the first frequency based on the local clock signals. In some embodiments, a staggered, multi-phase data sequence is converted to the output data sequence.

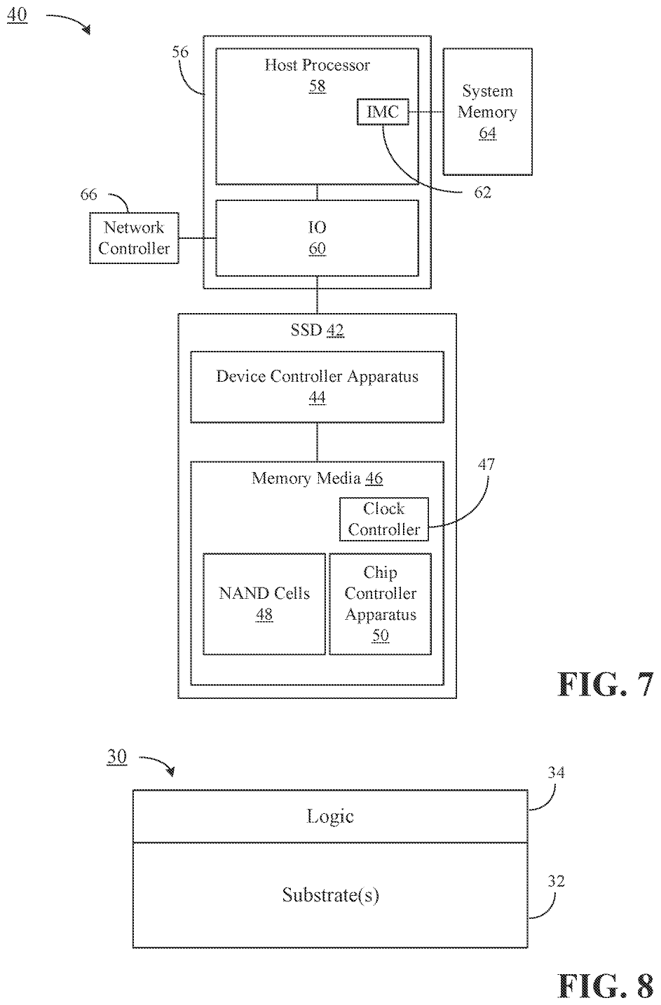

FIG. 7 is a block diagram of an example of a performance-enhanced computing system 40 according to one or more embodiments, with reference to components and features described herein including but not limited to the figures and associated description. The system 40 can be part of a server (e.g., a cloud server), desktop computer, notebook computer, tablet computer, convertible tablet, smart television (TV), personal digital assistant (PDA), mobile Internet device (MID), smart phone, wearable device, media player, vehicle, robot, Internet of Things (IoT) device, drone, autonomous vehicle, etc., or any combination thereof. In the illustrated example, an input/output (IO) module 60 is communicatively coupled to a solid state drive (SSD) 42 and a network controller 66 (e.g., wired, wireless).

The system 40 can also include a host processor 58 (e.g., central processing unit/CPU) that includes an integrated memory controller (IMC) 62, wherein the illustrated IMC 62 communicates with a system memory 64 (e.g., DRAM) over a bus or other suitable communication interface. In embodiments the host processor 58 and the IO module 60 are integrated onto a shared semiconductor die 56 in a system on chip (SoC) architecture.

In embodiments the SSD 42 includes a device controller apparatus 44 coupled to memory media 46 (e.g., non-volatile memory (NVM) media). In embodiments, the device controller apparatus 44 corresponds to the memory controller 510 (FIG. 5, already discussed). In embodiments, the memory media 46 includes a chip controller apparatus 50 coupled to a plurality of NAND cells 48. In embodiments, the memory media 46 corresponds to the memory device 400 (FIG. 4, already discussed) and/or to a non-volatile memory device 520 (FIG. 5, already discussed). In some embodiments, the chip controller apparatus 50 includes logic to perform operations by the control logic 411 (FIG. 4) and/or the firmware 414 (FIG. 4), including operations of the method 600 (FIG. 6). In embodiments the SSD 42 includes or corresponds to the data storage device 500 (FIG. 5).

In embodiments, a clock controller 47 includes logic to implement and/or perform operations by the memory clocking system 200 and/or components thereof (FIGS. 2A-2C, already discussed) and/or operations of the method 600 (FIG. 6, already discussed). In some embodiments, all or portions of the clock controller 47 are incorporated within or implemented by the chip controller apparatus 50.

The computing system 40 is therefore performance-enhanced at least to the extent that the memory clocking system uses multi-phase clock signals at a fraction of the incoming clock rate and synchronizes the data pipeline using only the rising edges of the clock signals. The memory arrangement of the SSD 42 (including operations of the memory clocking system) thus enables operation of the memory device at higher clock speeds while avoiding the degradation of clock signals in existing designs.

FIG. 8 is a block diagram illustrating an example semiconductor apparatus 30 according to one or more embodiments, with reference to components and features described herein including but not limited to the figures and associated description. The semiconductor apparatus 30 can be implemented, e.g., as a chip, die, or other semiconductor package. The semiconductor apparatus 30 can include one or more substrates 32 comprised of, e.g., silicon, sapphire, gallium arsenide, etc. The semiconductor apparatus 30 can also include logic 34 comprised of, e.g., transistor array(s) and other integrated circuit (IC) components) coupled to the substrate(s) 32. The logic 34 can be implemented at least partly in configurable logic or fixed-functionality logic hardware. The logic 34 can implement the system on chip (SoC) 56 and/or the SSD 42 (or components thereof) described above with reference to FIG. 7. The logic 34 can implement one or more aspects of the processes described above, including the method 600. The logic 34 can implement one or more aspects of the memory clocking system 200 (FIGS. 2A-2C). The apparatus 30 is therefore considered to be performance-enhanced at least to the extent that that the memory clocking system uses multi-phase clock signals at a fraction of the incoming clock rate and synchronizes the data pipeline using only the rising edges of the clock signals, thus enabling operation of the memory device at higher clock speeds while avoiding the degradation of clock signals in existing designs.

The semiconductor apparatus 30 can be constructed using any appropriate semiconductor manufacturing processes or techniques. For example, the logic 34 can include transistor channel regions that are positioned (e.g., embedded) within the substrate(s) 32. Thus, the interface between the logic 34 and the substrate(s) 32 may not be an abrupt junction. The logic 34 can also be considered to include an epitaxial layer that is grown on an initial wafer of the substrate(s) 32.

Embodiments of each of the above systems, devices, components and/or methods, including the memory clocking system 200, the clock divider/controller 220, the local clock generators 240, the local clock generator 340, the memory device 400, the data storage device 500, the method 600, and/or any other system or device components, or portions thereof, can be implemented in hardware, software, or any suitable combination thereof. For example, hardware implementations may include configurable logic, fixed-functionality logic, or any combination thereof. Examples of configurable logic include suitably configured PLAs, FPGAs, CPLDs, and general purpose microprocessors. Examples of fixed-functionality logic include suitably configured ASICs, combinational logic circuits, and sequential logic circuits. The configurable or fixed-functionality logic can be implemented with CMOS logic circuits, TTL logic circuits, or other circuits. Alternatively, or additionally, all or portions of the foregoing systems and/or components and/or methods can be implemented in one or more modules as a set of program or logic instructions stored in a machine- or computer-readable storage medium such as RAM, ROM, PROM, firmware, flash memory, etc., to be executed by a processor or computing device.

### Additional Notes and Examples

Example A1 includes a semiconductor apparatus comprising one or more substrates, and logic coupled to the one or more substrates, wherein the logic is implemented at least partly in one or more of configurable or fixed-functionality hardware, the logic to generate, based on a first clock signal having a first frequency, multi-phase clock signals for a memory device having a second frequency, wherein the second frequency is a fraction of the first frequency, generate local clock signals for data channels of the memory device based on the multi-phase clock signals, wherein the local clock signals are synchronous with respective rising edges of the multi-phase clock signals, and provide output data for the data channels of the memory device in an output data sequence based on the local clock signals.

Example A2 includes the apparatus of Example A1, wherein the logic is to bypass use of a trailing edge of respective ones of the multi-phase clock signals.

Example A3 includes the apparatus of Example A1 or A2, wherein the multi-phase clock signals are generated based on dividing the first clock signal.

Example A4 includes the apparatus of Example A1, A2 or A3, wherein the second frequency is one-half of the first frequency.

Example A5 includes the apparatus of any of Examples A1-A4, wherein the multi-phase clock signals are four-phase clock signals.

Example A6 includes the apparatus of any of Examples A1-A5, wherein the output data is clocked out at an effective rate equal to the first frequency based on the local clock signals.

Example A7 includes the apparatus of any of Examples A1-A6, wherein the logic is to convert a staggered, multi-phase data sequence to the output data sequence for the memory device.

Example D1 includes a data storage device comprising a memory controller to generate a first clock signal having a first frequency, and one or more memory devices, wherein each memory device of the one or more memory devices comprises one or more substrates, and logic coupled to the one or more substrates, wherein the logic is implemented at least partly in one or more of configurable or fixed-functionality hardware, the logic to generate, based on a first clock signal having a first frequency, multi-phase clock signals for the memory device having a second frequency, wherein the second frequency is a fraction of the first frequency, generate local clock signals for data channels of the memory device based on the multi-phase clock signals, wherein the local clock signals are synchronous with respective rising edges of the multi-phase clock signals, and provide output data for the data channels of the memory device in an output data sequence based on the local clock signals.

Example D2 includes the data storage device of Example D1, wherein the logic is to bypass use of a trailing edge of respective ones of the multi-phase clock signals.

Example D3 includes the data storage device of Example D1 or D2, wherein the multi-phase clock signals are generated based on dividing the first clock signal.

Example D4 includes the data storage device of Example D1, D2 or D3, wherein the second frequency is one-half of the first frequency.

Example D5 includes the data storage device of any of Examples D1-D4, wherein the multi-phase clock signals are four-phase clock signals.

Example D6 includes the data storage device of any of Examples D1-D5, wherein the output data is clocked out at an effective rate equal to the first frequency based on the local clock signals.

Example D7 includes the data storage device of any of Examples D1-D6, wherein the logic is to convert a staggered, multi-phase data sequence to the output data sequence for the memory device.

Example D8 includes the storage device of any of Examples D1-D7, wherein the one or more memory devices comprises a plurality of memory devices.

Example M1 includes a method comprising generating, based on a first clock signal having a first frequency, multi-phase clock signals for a memory device having a second frequency, wherein the second frequency is a fraction of the first frequency, generating local clock signals for data channels of the memory device based on the multi-phase clock signals, wherein the local clock signals are synchronous with respective rising edges of the multi-phase clock signals, and providing output data for the data channels of the memory device in an output data sequence based on the local clock signals.

Example M2 includes the method of Example M1, further comprising bypassing use of a trailing edge of respective ones of the multi-phase clock signals.

Example M3 includes the method of Example M1 or M2, wherein the multi-phase clock signals are generated based on dividing the first clock signal.

Example M4 includes the method of Example M1, M2 or M3, wherein the second frequency is one-half of the first frequency.

Example M5 includes the method of any of Examples M1-M4, wherein the multi-phase clock signals are four-phase clock signals.

Example M6 includes the method of any of Examples M1-M5, wherein the output data is clocked out at an effective rate equal to the first frequency based on the local clock signals.

Example M7 includes the method of any of Examples M1-M6, wherein providing the output data comprises converting a staggered, multi-phase data sequence to the output data sequence for the memory device.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections, including logical connections via intermediate components (e.g., device A may be coupled to device C via device B). In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A, B, C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A semiconductor apparatus comprising:
one or more substrates; and
logic coupled to the one or more substrates, wherein the logic is implemented at least partly in one or more of configurable or fixed-functionality hardware, the logic to:
generate, based on a first clock signal having a first frequency, multi-phase clock signals for a memory device having a second frequency, wherein the second frequency is a fraction of the first frequency;
generate local clock signals for data channels of the memory device based on the multi-phase clock signals, wherein the local clock signals are synchronous with respective rising edges of the multi-phase clock signals; and
provide output data for the data channels of the memory device in an output data sequence based on the local clock signals.

2. The apparatus of claim 1, wherein the logic is to bypass use of a trailing edge of respective ones of the multi-phase clock signals.

3. The apparatus of claim 1, wherein the multi-phase clock signals are generated based on dividing the first clock signal.

4. The apparatus of claim 1, wherein the second frequency is one-half of the first frequency.

5. The apparatus of claim 4, wherein the multi-phase clock signals are four-phase clock signals.

6. The apparatus of claim 1, wherein the output data is clocked out at an effective rate equal to the first frequency based on the local clock signals.

7. The apparatus of claim 1, wherein the logic is to convert a staggered, multi-phase data sequence to the output data sequence for the memory device.

8. A data storage device comprising:
a memory controller to generate a first clock signal having a first frequency; and
one or more memory devices, wherein each memory device of the one or more memory devices comprises:
one or more substrates; and
logic coupled to the one or more substrates, wherein the logic is implemented at least partly in one or more of configurable or fixed-functionality hardware, the logic to:
generate, based on a first clock signal having a first frequency, multi-phase clock signals for the memory device having a second frequency, wherein the second frequency is a fraction of the first frequency;
generate local clock signals for data channels of the memory device based on the multi-phase clock signals, wherein the local clock signals are synchronous with respective rising edges of the multi-phase clock signals; and
provide output data for the data channels of the memory device in an output data sequence based on the local clock signals.

9. The data storage device of claim 8, wherein the logic is to bypass use of a trailing edge of respective ones of the multi-phase clock signals.

10. The data storage device of claim 8, wherein the multi-phase clock signals are generated based on dividing the first clock signal.

11. The data storage device of claim 8, wherein the second frequency is one-half of the first frequency.

12. The data storage device of claim 11, wherein the multi-phase clock signals are four-phase clock signals.

13. The data storage device of claim 8, wherein the output data is clocked out at an effective rate equal to the first frequency based on the local clock signals.

14. The data storage device of claim 8, wherein the logic is to convert a staggered, multi-phase data sequence to the output data sequence for the memory device.

15. The storage device of claim 8, wherein the one or more memory devices comprises a plurality of memory devices.

16. A method comprising:
generating, based on a first clock signal having a first frequency, multi-phase clock signals for a memory device having a second frequency, wherein the second frequency is a fraction of the first frequency;
generating local clock signals for data channels of the memory device based on the multi-phase clock signals, wherein the local clock signals are synchronous with respective rising edges of the multi-phase clock signals; and
providing output data for the data channels of the memory device in an output data sequence based on the local clock signals.

17. The method of claim 16, further comprising bypassing use of a trailing edge of respective ones of the multi-phase clock signals.

18. The method of claim 16, wherein the multi-phase clock signals are generated based on dividing the first clock signal.

19. The method of claim 16, wherein the second frequency is one-half of the first frequency, and wherein the multi-phase clock signals are four-phase clock signals.

20. The method of claim 16, wherein the output data is clocked out at an effective rate equal to the first frequency based on the local clock signals, and wherein providing the output data comprises converting a staggered, multi-phase data sequence to the output data sequence for the memory device.
